(19) United States
(12) Patent Application Publication
(10) Pub. No.: US 2023/0314949 A1
(43) Pub. Date: Oct. 5, 2023

(54) METHOD FOR LITHOGRAPHY USING MIDDLE LAYER WITH POROUS TOP SURFACE

(71) Applicant: TAIWAN SEMICONDUCTOR MANUFACTURING COMPANY, LTD., Hsinchu (TW)

(72) Inventors: Yuan Chih LO, Hsinchu City (TW); Ching-Yu CHANG, Yilang County (TW)

(73) Assignee: TAIWAN SEMICONDUCTOR MANUFACTURING COMPANY, LTD., Hsinchu (TW)

(21) Appl. No.: 17/710,218

(22) Filed: Mar. 31, 2022

(51) Int. Cl. G03F 7/16; G03F 7/09

(52) U.S. Cl. CPC G03F 7/168; G03F 7/094

(57) ABSTRACT

A method includes depositing a middle layer over a substrate. The middle layer includes sacrificial additives. A heating process is performed to cross-link the middle layer. The sacrificial additives are floated onto a top surface of the middle layer. The sacrificial additives are removed from the middle layer after the heating process is performed. A photoresist layer is deposited over the middle layer. The photoresist layer is exposed to a radiation beam. The photoresist layer is developed after the photoresist layer is exposed.

### BACKGROUND

As consumer devices have gotten smaller and smaller in response to consumer demand, the individual components of these devices are decreased in size as well. Semiconductor devices, which make up a major component of devices such as mobile phones, computer tablets, and the like, have been pressured to become smaller and smaller, with a corresponding pressure on the individual devices (e.g., transistors, resistors, capacitors, etc.) within the semiconductor devices to also be reduced in size.

One enabling technology that is used in the manufacturing processes of semiconductor devices is the use of photolithographic materials. Such materials are applied to a surface of a layer to be patterned and then exposed to an energy that has itself been patterned. Such an exposure modifies the chemical and physical properties of the exposed regions of the photosensitive material. This modification, along with the lack of modification in regions of the photosensitive material that were not exposed, can be exploited to remove one region without removing the other.

However, as the size of individual devices has decreased, process windows for photolithographic processing has become tighter and tighter. As such, advances in the field of photolithographic processing are necessary to maintain the ability to scale down the devices, and further improvements are needed in order to meet the desired design criteria such that the march towards smaller and smaller components may be maintained.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of some embodiment of a method of making a semiconductor device according to aspects of the present disclosure.

FIGS. 2-11B are cross-sectional views of a semiconductor device fabricated according to one or more operations of the method of FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

As feature size decreases, line width resolution suffers. Residual photoresist or scum is difficult to remove in small pitch and high aspect ratio patterns. To improve line width roughness in extreme ultraviolet (EUV) lithography operations a photoresist middle layer is used according to embodiments of the disclosure. Sacrificial additives are added into the photoresist middle layer to roughen the top surface of the photoresist middle layer. The roughed (or porous) top surface of the photoresist middle layer enhances heat convection in the photoresist top layer during the soft-baking process, thereby helping pushing photo decomposable quenchers (PDQs) in the photoresist top layer upwards. The PDQ-rich top of the photoresist top layer reduces the acid diffusion during the post-exposure baking process and thus reduces tapered head of PR profile as well as broken defect.

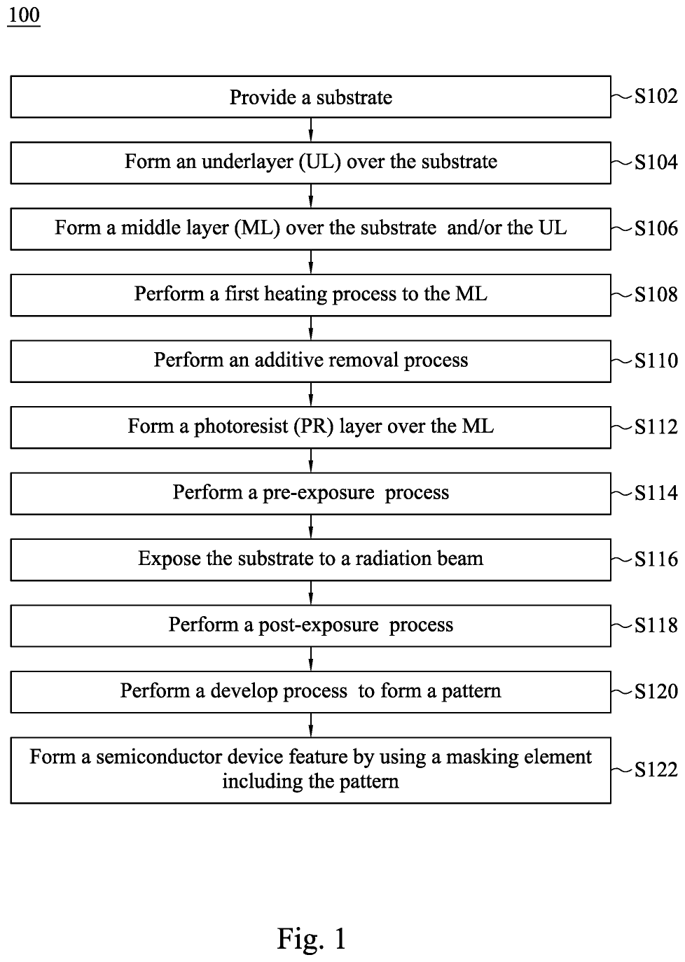

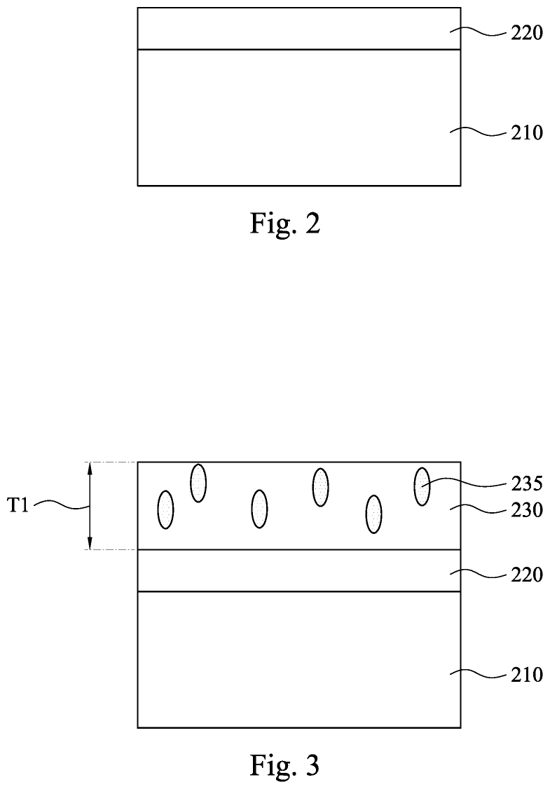

FIG. 1 is a flowchart of some embodiment of a method 100 of making a semiconductor device according to aspects of the present disclosure. FIGS. 2-11B are cross-sectional views of a semiconductor device 200 fabricated according to one or more operations of the method 100 of FIG. 1. It is understood that the method 100 includes operations having features of a complementary metal-oxide-semiconductor (CMOS) technology process flow and thus, are only described briefly herein. Additional operations may be performed before, after, and/or during the method 100.

It is also understood that parts of the semiconductor device 200 may be fabricated by complementary metal-oxide-semiconductor (CMOS) technology process flow, and thus some processes are only briefly described herein. Further, the semiconductor device 200 may include various other devices and features, such as additional transistors, bipolar junction transistors, resistors, capacitors, diodes, fuses, etc., but is simplified for a better understanding of the inventive concepts of the present disclosure.

The semiconductor device 200 may be an intermediate device fabricated during processing of an integrated circuit, or portion thereof, that may include static random access memory (SRAM) and/or other logic circuits, passive components such as resistors, capacitors, and inductors, and active components such as P-channel field effect transistors (PFET), N-channel FET (NFET), metal-oxide semiconductor field effect transistors (MOSFET), complementary metal-oxide semiconductor (CMOS) transistors, bipolar transistors, high voltage transistors, high frequency transistors, other memory cells, and combinations thereof. The semiconductor device 200 includes a plurality of semiconductor devices (e.g., transistors), which may be interconnected.

As shown in operation S102 of the method 100, a substrate is provided. The substrate may be a semiconductor substrate, such as a semiconductor wafer. The substrate may include silicon in a crystalline structure. In alternative embodiments, the substrate may include germanium, silicon germanium, silicon carbide, gallium arsenide, indium arsenide, indium phosphide, and/or other suitable materials. The substrate may be a silicon-on-insulator (SOI) substrate. The substrate may include a plurality of layers and/or features formed on the semiconductor substrate including doped regions or wells, isolation regions such as shallow trench isolation (STI) features, conductive layers, insulating layers, and various other suitable features. For example, the substrate may include one or more target layers, which are desired to patterned. Referring to the example of FIG. 2, a substrate 210 is illustrated. In some embodiments, the substrate 210 has any plurality of layers (conductive layer, insulator layer) or features (source/drain regions, gate structures, interconnect lines and vias), formed thereon. The substrate 210 may include one or more target layers disposed on a semiconductor substrate; the target layers suitable for patterning by the method 100. Exemplary target layers include gate layers, interconnect layers, and/or other suitable layers. In some embodiment, the patterning by the method 100 may be suitable to etch portions of the semiconductor substrate itself (e.g., such as in the formation of fins for a fin-type field effect transistor).

The method 100 then proceeds to operation S104 where an underlayer (UL) of a trilayer patterning stack is formed on the substrate. For example, in FIG. 2, an underlayer 220 is formed over the substrate 210. The underlayer 220 may be a first (e.g., nearest the substrate) layer of a trilayer patterning stack also referred to as a tri-layer resist. In some embodiments, the underlayer 220 is organic. In some other embodiments, the organic material includes a plurality of monomers or polymers that are not cross-linked. The underlayer 220 may contain a material that is patternable and/or have a composition tuned to provide anti-reflection properties. Exemplary materials for the underlayer 220 include a carbon backbone polymer. In some embodiments, the underlayer 220 is omitted. In some embodiments, the underlayer 220 may be formed by a spin coating process. In some other embodiments, the underlayer 220 may be formed by another suitable deposition process.

The method 100 then proceeds to operation S106 where a middle layer (ML) over the substrate and/or the UL. For example, in FIG. 3, a middle layer 230 is formed over the underlayer 220. The middle layer 230 may be a second layer of a trilayer patterning stack. The middle layer may have a composition that provides an anti-reflective properties and/or hard mask properties for the lithography process. In some embodiments, the middle layer 230 includes a silicon containing layer (e.g., silicon hard mask material). The middle layer 230 may include a silicon-containing inorganic polymer. In some other embodiments, the middle layer 230 includes a siloxane polymer (e.g., a polymer having a backbone of O—Si—O—Si— etc.). Alternatively, the middle layer 230 includes a siloxane as polymer backbone with carbon branches including (cyclic)alkyl, (cyclic)alkenyl, (cyclic)alkynyl, aromatic rings, or combinations thereof. The silicon ratio of the middle layer material may be controlled such as to control the etch rate. In some embodiments, the middle layer 230 does not include photo-acid generator (PAG). That is, the middle layer 230 is (substantially) PAG-free. However, in some other embodiments, the middle layer 230 includes photo-acid generator (PAG). In some embodiments, the middle layer 230 has a thickness T1 in a range from about 10 nm to about 100 nm.

The middle layer 230 may be formed by a spin-on coating process, chemical vapor deposition process (CVD), physical vapor deposition (PVD) process, and/or other suitable deposition processes. During the deposition of the middle layer 230, sacrificial additives 235 are added in the middle layer 230, such that the sacrificial additives 235 are distributed in the middle layer 230. In some embodiments, the sacrificial additives 235 include polyacrylate, polymethacrylate, polyflouroalcohol, polyester, polyimide, polyether, the like, or the abovementioned polymer including perfluoroalkyl sidechain which is not crosslinked with Si-polymer. In some embodiments, the sacrificial additives 235 include alkylsulphate, silyl ethers, nanoclusters, the like, or the abovementioned molecules including perfluoroalkyl sidechain. In some embodiments, the sacrificial additives 235 is free of Si—X structure, which is reactive to siloxane condensation, and X includes Cl, Br, OAc (Ac is actyl group), OH and OR (R is (cyclic)alkyl, (cyclic)alkenyl, (cyclic)alkynyl, aromatic and/or their derivatives with halide substitution). In some embodiments, the middle layer 230 further includes a solvent which may be any alcohol type solvent, ether type solvent, or ester type solvent mixed with water. The solvent does not dissolve the underlayer 220 during the ML deposition process.

In some embodiments, the sacrificial additives 235 include fluorine-containing materials, e.g., CF₂, C₂F₄, CₓF_{y} (x is 1 to 10), or the like. With more fluorine (e.g., x is 10 or more), polymers in the sacrificial additives 235 are easier to be assembled. In some embodiments, the sacrificial additives 235 may be about 500 ppm to about 10% by weight in the middle layer 230. In some embodiments, sizes of the sacrificial additives 235 are in a range from about 10 nm to about 100 nm. The top surface of the middle layer 230 may not rough enough after the additive removal process (see operation S110) is performed if the weight of the sacrificial additives 235 is out of the aforementioned range and/or if the sizes of the sacrificial additives 235 are out of the aforementioned range.

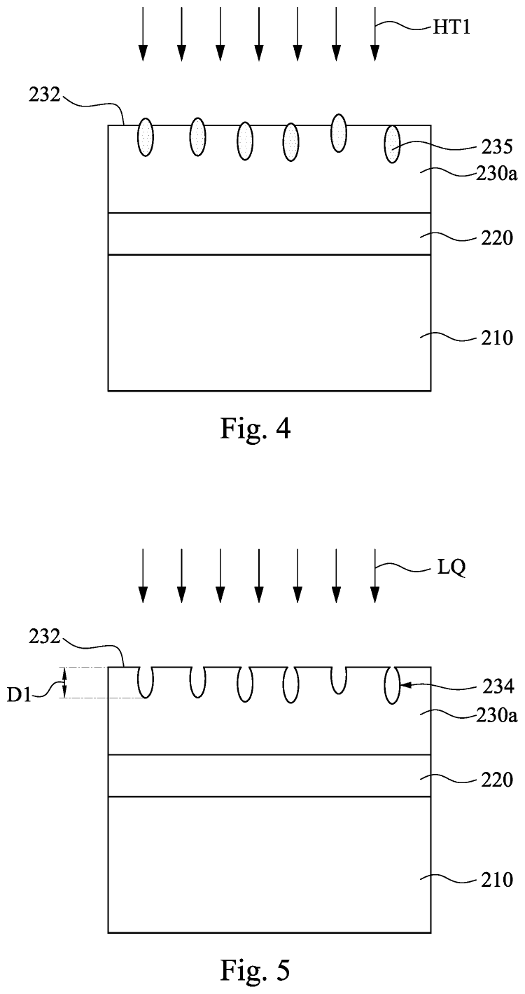

The method 100 then proceeds to operation S108 where a first heating process is performed to the middle layer. During the deposition of the middle layer 230, the sacrificial additives 235 and the polymers of the middle layer 230 are both non-cross-linked. As shown in FIG. 4, a first heating process HT1 is performed. That is, the middle layer 230 is thermally baked for cross-linking. The first heating process HT1 may be performed at a temperature of about 80° C. to about 250° C. to form a cross-linked middle layer 230a, as shown in FIG. 4. If the temperature is greater than about 250° C., the middle layer 230a may be damaged, and if the temperature is lower than about 80° C., the middle layer 230 may be non-cross-linked. The heating causes the crosslinking groups to cross-link. As mentioned above, the sacrificial additives 235 are non-cross-linked. During the first heating process HT1, the sacrificial additives 235 remain non-cross-linked since the sacrificial additives 235 are free of Si—X structures as mentioned above. The sacrificial additives 235 have weights lighter than the cross-linked middle layer 230a due to the perfluoroalkyl sidechain thereof. Thus, the sacrificial additives 235 float to the top surface 232 of the cross-linked middle layer 230a.

After the first heating process HT1, the middle layer 230a provides a layer having a first or top region having a greater percentage of additive components than a second or lower region. For example, a top region may include about 0.1% to about 10% sacrificial additives 235 by weight, while a bottom region may include less than about 0.1% sacrificial additives 235 by weight or substantially no sacrificial additives 235.

The method 100 then proceeds to operation S110 where an additive removal process is performed. As shown in FIG. 5, liquid (such as solvent) LQ is applied to the top surface 232 of the cross-linked middle layer 230a to remove the sacrificial additives 235 (see FIG. 4). The liquid LQ reacts with non-cross-linked materials but not with cross-linked materials. As mentioned above, the sacrificial additives 235 are non-cross-linked (while the middle layer 230a is cross-linked), the liquid LQ reacts with the sacrificial additives 235 and removes the sacrificial additives 235 from the top surface 232 of the middle layer 230a. Hence, holes (or recesses) 234 are formed in the middle layer 230a at the top surface 232 thereof. In some embodiments, the liquid LQ1 includes Propylene glycol monomethylether (PGME), Propylene glycol monomethylether acetate (PGMEA)), n-butyl acetate (nBA), or combinations thereof. For example, the liquid LQ1 is OK73 (about 70% PGME and about 30% PGMEA.

Thus, the middle layer 230a includes a roughed (porous) top surface 232 that allows for a solvent of the overlying photoresist disposed in. In some embodiments, a depth D1 of the holes 234 is in a range from about 10 nm to about 100 nm. In some embodiments, the holes 234 occupy about 1% to about 50% by area in the top surface 232 of the middle layer 230a.

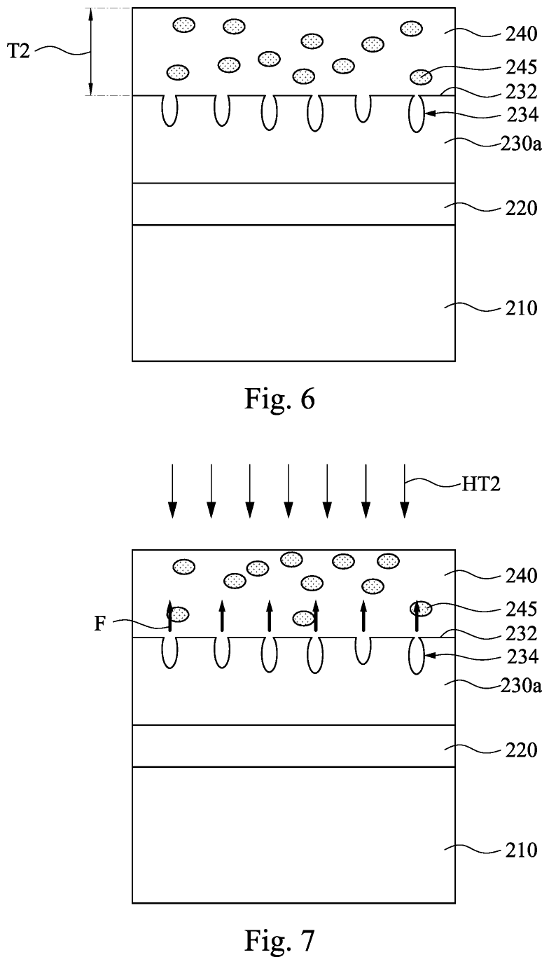

The method 100 then proceeds to operation S112 where a photoresist (PR) layer is formed over the middle layer. As shown in FIG. 6, a PR (top) layer 240 is formed over the middle layer 230a. The PR layer 240 may be a third, and top, layer of a trilayer patterning stack. The PR layer 240 may be a photosensitive layer operable to be patterned by a radiation. The chemical properties of the photoresist regions struck by incident radiation change in a manner that depends on the type of photoresist used.

The PR layer 240 is either a positive tone resist or a negative tone resist. A positive tone resist refers to a photoresist material that when exposed to radiation, such as UV light, becomes soluble in a developer, while the region of the photoresist that is non-exposed (or exposed less) is insoluble in the developer. A negative tone resist, on the other hand, refers to a photoresist material that when exposed to radiation becomes insoluble in the developer, while the region of the photoresist that is non-exposed (or exposed less) is soluble in the developer. The region of a negative resist that becomes insoluble upon exposure to radiation may become insoluble due to a cross-linking reaction caused by the exposure to radiation.

Whether a resist is a positive tone or negative tone may depend on the type of developer used to develop the resist. For example, some positive tone photoresists provide a positive pattern, (i.e. the exposed regions are removed by the developer), when the developer is an aqueous-based developer, such as a tetramethylammonium hydroxide (TMAH) solution. On the other hand, the same photoresist provides a negative pattern (i.e. —the unexposed regions are removed by the developer) when the developer is an organic solvent. Further, in some negative tone photoresists developed with the TMAH solution, the unexposed regions of the photoresist are removed by the TMAH, and the exposed regions of the photoresist, that undergo cross-linking upon exposure to actinic radiation, remain on the substrate after development.

The PR layer 240 may be a carbon-containing layer. The PR layer 240 according to the present disclosure includes a polymer along with one or more acids in a solvent, in some embodiments. In some embodiments, the polymer includes polyacrylate, polymethacrylate, polyflouroalcohol, polyester, polyimide, polyether, polyalcohol, or combinations thereof.

The acids are bound on the polymers, and/or the acids are blend into the polymers to inhibit quencher acid length. The acids may be organic acids (e.g., R—COOH, RSO₃H), photo acid generator (PAG), or thermal acid generator (TAG). As mentioned above, the middle layer 230a is substantially PAG-free, such that a concentration of the PAGs in the photoresist layer 240 is greater than a concentration of the PAGs in the middle layer 230a. In some embodiments in which the acids are a photoacid generator, the acids include halogenated triazines, onium salts, diazonium salts, aromatic diazonium salts, phosphonium salts, sulfonium salts, iodonium salts, imide sulfonate, oxime sulfonate, diazodisulfone, disulfone, o-nitrobenzylsulfonate, sulfonated esters, halogenated sulfonyloxy dicarboximides, diazodisulfones, α-cyanooxyamine-sulfonates, imidesulfonates, ketodiazosulfones, sulfonyldiazoesters, 1,2-di(arylsulfonyl)hydrazines, nitrobenzyl esters, and the s-triazine derivatives, combinations of these, or the like.

Specific examples of photoacid generators include α-(trifluoromethylsulfonyloxy)-bicyclo[2.2.1]hept-5-ene-2,3-dicarb-o-ximide (MDT), N-hydroxy-naphthalimide (DDSN), benzoin tosylate, t-butylphenyl-α-(p-toluenesulfonyloxy)-acetate and t-butyl-α-(p-toluenesulfonyloxy)-acetate, triarylsulfonium and diaryliodonium hexafluoroantimonates, hexafluoroarsenates, trifluoromethanesulfonates, iodonium perfluorooctanesulfonate, N-camphorsulfonyloxynaphthalimide, N-pentafluorophenylsulfonyloxynaphthalimide, ionic iodonium sulfonates such as diaryl iodonium (alkyl or aryl)sulfonate and bis-(di-t-butylphenyl)iodonium camphanylsulfonate, perfluoroalkanesulfonates such as perfluoropentanesulfonate, perfluorooctanesulfonate, perfluoromethanesulfonate, aryl (e.g., phenyl or benzyl)triflates such as triphenylsulfonium triflate or bis-(t-butylphenyl)iodonium triflate; pyrogallol derivatives (e.g., trimesylate of pyrogallol), trifluoromethanesulfonate esters of hydroxyimides, α,α′-bis-sulfonyl-diazomethanes, sulfonate esters of nitro-substituted benzyl alcohols, naphthoquinone-4-diazides, alkyl disulfones, or the like.

In some embodiments, the PR layer 240 further includes photo decomposable quencher (PDQ) 245. Such PBGs change the PR layer's base level after exposure. Thus, it modifies the aerial image for better imaging performance. In some embodiments, the PBQs include triphenylsulfonium hydroxide, triphenylsulfonium antimony hexafluoride, and triphenylsulfonium trifyl.

In some embodiments, the PR layer 240 further includes quencher, such as R₃N, R₂NH, RNH₂, thermal base generator (TBG), and/or photobase generators (PBG). The PBGs include quaternary ammonium dithiocarbamates, a aminoketones, oxime-urethane containing molecules such as dibenzophenoneoxime hexamethylene diurethan, ammonium tetraorganylborate salts, and N-(2-nitrobenzyloxycarbonyl)cyclic amines, combinations of these, or the like. The quenchers are bound on the polymers, and/or the quenchers are blend into the polymers to inhibit quencher diffusion length.

In some embodiments, the PBG includes quaternary ammonium dithiocarbamates, a aminoketones, oxime-urethane containing molecules such as dibenzophenoneoxime hexamethylene diurethan, ammonium tetraorganylborate salts, and N-(2-nitrobenzyloxycarbonyl)cyclic amines, combinations of these, or the like.

As one of ordinary skill in the art will recognize, the chemical compounds listed herein are merely intended as illustrated examples of the acids/quenchers and are not intended to limit the embodiments to only those chemicals specifically described. Rather, any suitable chemicals may be used, and such chemicals are intended to be included within the scope of the present embodiments.

In some embodiments, a cross-linking agent is added to the PR layer 240. The cross-linking agent reacts with one group from one of the hydrocarbon structures in the polymer resin and also reacts with a second group from a separate one of the hydrocarbon structures in order to cross-link and bond the two hydrocarbon structures together. This bonding and cross-linking increases the molecular weight of the polymer products of the cross-linking reaction and increases the overall linking density of the photoresist. Such an increase in density and linking density helps to improve the resist pattern.

Alternatively, instead of or in addition to the cross-linking agent being added to the PR layer 240, a coupling reagent is added in some embodiments, in which the coupling reagent is added in addition to the cross-linking agent. The coupling reagent assists the cross-linking reaction by reacting with the groups on the hydrocarbon structure in the polymer resin before the cross-linking reagent, allowing for a reduction in the reaction energy of the cross-linking reaction and an increase in the rate of reaction. The bonded coupling reagent then reacts with the cross-linking agent, thereby coupling the cross-linking agent to the polymer resin.

Alternatively, in some embodiments in which the coupling reagent is added to the PR layer 240 without the cross-linking agent, the coupling reagent is used to couple one group from one of the hydrocarbon structures in the polymer to a second group from a separate one of the hydrocarbon structures in order to cross-link and bond the two polymers together. However, in such embodiments the coupling reagent, unlike the cross-linking agent, does not remain as part of the polymer, and only assists in bonding one hydrocarbon structure directly to another hydrocarbon structure.

The individual components of the PR layer 240 are placed into a solvent in order to aid in the mixing and dispensing of the photoresist. To aid in the mixing and dispensing of the photoresist, the solvent is chosen at least in part based upon the materials chosen for the polymers as well as the components. In some embodiments, the solvent is chosen such that the polymers and the components can be evenly dissolved into the solvent and dispensed upon the layer to be patterned.

In some embodiments, the solvent is an organic solvent, and includes one or more of any suitable solvent such as ketones, alcohols, polyalcohols, ethers, glycol ethers, cyclic ethers, aromatic hydrocarbons, esters, propionates, lactates, lactic esters, alkylene glycol monoalkyl ethers, alkyl lactates, alkyl alkoxypropionates, cyclic lactones, monoketone compounds that contain a ring, alkylene carbonates, alkyl alkoxyacetate, alkyl pyruvates, lactate esters, ethylene glycol alkyl ether acetates, diethylene glycols, propylene glycol alkyl ether acetates, alkylene glycol alkyl ether esters, alkylene glycol monoalkyl esters, or the like.

The materials listed and described above as examples of materials that may be used for the solvent component of the photoresist composition are merely illustrative and are not intended to limit the embodiments. Rather, any suitable materials that dissolve the polymer and the photoacid generator may be used to help mix and apply the photoresist underlayer. Such materials are intended to be included within the scope of the embodiments.

Once ready, the photoresist is applied onto the layer to be patterned, as shown in FIG. 6, such as the substrate 200 to form the PR layer 240. In some embodiments, the photoresist is applied using a process such as a spin-on coating process, a dip coating method, an air-knife coating method, a curtain coating method, a wire-bar coating method, a gravure coating method, a lamination method, an extrusion coating method, combinations of these, or the like. In some embodiments, the PR layer 240 thickness T2 ranges from about 10 nm to about 200 nm.

As shown in FIG. 6, due to the rough top surface 232 of the middle layer 230a, portions of the solvent in the PR layer 240 flow into the holes 234 of the top surface 232. As such, a contact area between the solvent in the PR layer 240 and the middle layer 230a is increased.

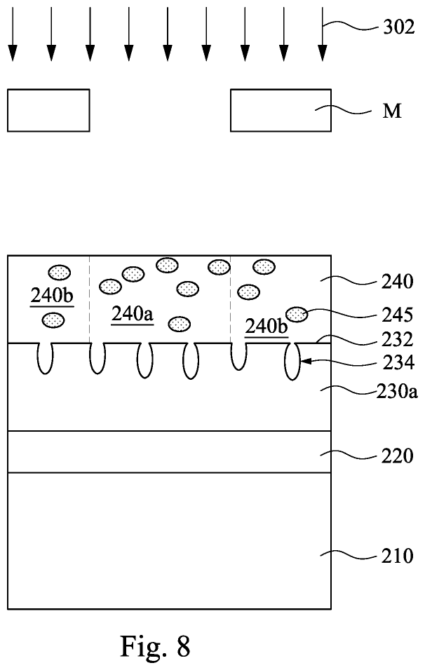

After the PR layer 240 has been applied to the substrate 210 in operation S112, a pre-exposure bake (or soft-bake) process to the PR layer 240 is performed in operation S114, in some embodiments, to cure and dry the PR layer 240 prior to radiation exposure (see FIG. 8). The curing and drying of the PR layer 240 removes the solvent component while leaving behind the polymer, the PACs, and the other chosen additives. In some embodiments, as shown in FIG. 7, the pre-exposure bake process, which may be a second heating process HT2, is performed at a temperature suitable to evaporate the solvent, such as about 70° C. to 250° C., although the precise temperature depends upon the materials chosen for the photoresist. The pre-exposure bake process is performed for a time sufficient to cure and dry the photoresist layer.

During the pre-exposure bake process, the middle layer 230a is heated as well. Portions of the solvent of the PR layer 240 in the holes 234 of the middle layer 230a are sufficiently heated because of the large contact area between the middle layer 230a and the portions of the solvent. The heated solvent then flows upward, which lead to a driving force F to push the PDQs 245 toward the top portion of the PR layer 240. Stated another way, the second heating process HT2 modifies a distribution of the PDQs 245 in the photoresist layer. Thus, the PR layer 240 provides a layer having a first or top region having a greater percentage of PDQs 245 than a second or lower region. That is, a concentration of the PDQs 245 in the top region of the PR layer 240 is greater than a concentration of the PDQs 245 in the bottom region of the PR layer 240. Stated another way, the concentration of the PDQs 245 in the PR layer 240 decreases downwardly and/or increases upwardly.

The method 100 then proceeds to operation S116 where the substrate is exposed to a radiation beam thereby patterning the PR layer. The radiation beam may expose the resist deposited on the substrate using a lithography system that provides a pattern of the radiation according to an IC design layout. In some embodiments, a lithography system includes an ultraviolet (UV) radiation, a deep ultraviolet (DUV) radiation, an extreme ultraviolet (EUV) radiation, an X-ray radiation, and/or other suitable radiation types. In alternative embodiments, a lithography system includes a charged particle lithography system, such as an electron beam or an ion beam lithography system.

Referring to the example of FIG. 8, a radiation beam 302, which is patterned by a mask (or a reticle) M, is incident the substrate 210 and specifically the PR layer 240. The regions 240a illustrate the portions of the resist that have been exposed to the radiation, and thus, a chemical change has occurred in those reasons. During the exposure process (i.e., the operation S116), the PAGs in the PR layer 240 interact with the radiation beam to generate acids. In the case of positive resist, the regions 240a are soluble in developer; in the case of negative resist, the regions 240a are insoluble in developer. The exposure process of operation S116, including as illustrated by the radiation beam 302, may generate an acid in the PR layer 240 (on account of the PAG) as described above.

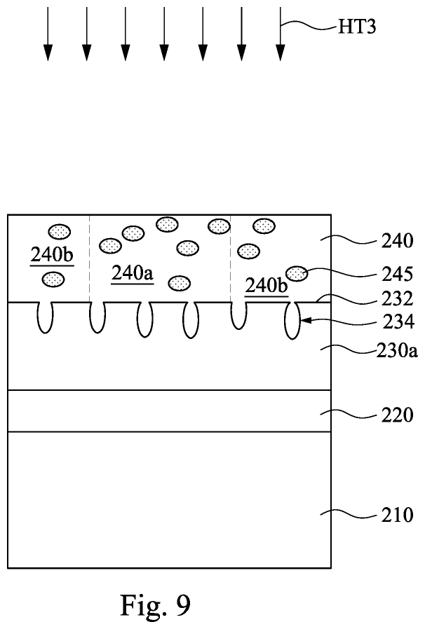

The method 100 then proceeds to operation S118 where a post-exposure bake (PEB) process is performed. The bake may be a hard bake. For example, as shown in FIG. 9, the PR layer 240 and the middle layer 230a are then subjected to a third heating process HT3. The third heating process HT3 of the PR layer 240 is performed at a temperature of about 70° C. to about 250° C.

During the PEB process, the acids generated in the PR layer 240 during the exposure process may be diffused in the PR layer 240. However, as shown in FIG. 9, the top region of the PR layer 240 includes more PDQs 245 (i.e., PDQ-rich), which reduce acid diffusion in the top region of the PR layer 240. As such, the acid diffusion issue at the top region of the PR layer 240 can be improved. On the other hand, the bottom region of the PR layer 240 is PDQ-poor or free of PDQs 245. The reduced PDQ concentration in the bottom region of the PR layer 240 facilitates acid diffusion and thus improves footing profile and scum defect at the bottom of the PR layer 240.

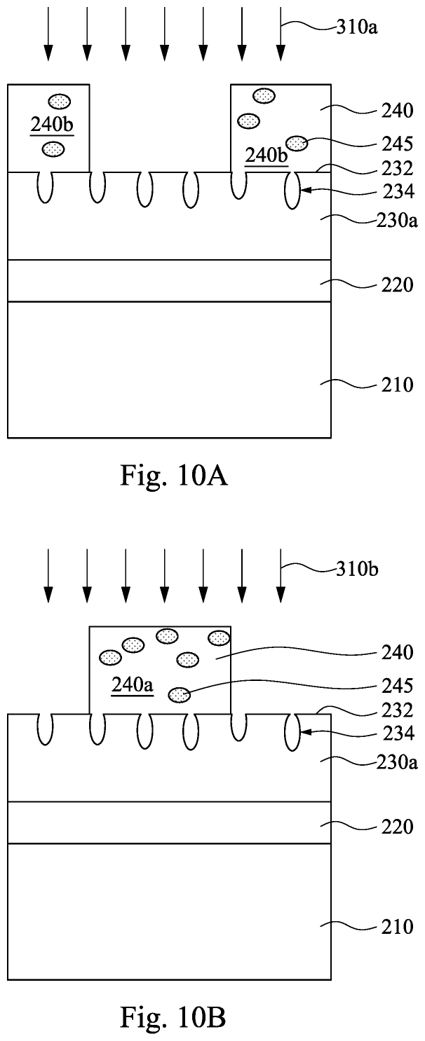

The method 100 then proceeds to operation S120 where the exposed PR layer is developed. As shown in FIGS. 10A and 10B, a developer 310 may be applied to the exposed resist to form a resist pattern on the substrate 210. In FIG. 10A, a positive tone developer 310a is applied in operation S120. The term “positive tone developer” refers to a developer that selectively dissolves and removes areas that received exposure dose (or an exposure dose above a predetermined threshold exposure dose value). In FIG. 10B, a negative tone developer 310b is applied in operation S120. The term “negative tone developer” refers to a developer that selectively dissolves and removes areas that not received exposure dose (or an exposure dose below a predetermined threshold exposure dose value).

In some embodiment, a developer may include an organic solvent or a mixture of organic solvents, such as methyl a-amyl ketone (MAK) or a mixture involving the MAK. In some other embodiments, a developer includes a water based developer, such as tetramethylammonium hydroxide (TMAH). Applying a developer includes spraying a developer on the exposed resist film, for example by a spin-on process.

Referring to the example of FIGS. 10A and 10B, a pattern is provided in the PR layer 240. The pattern is formed by applying the developer 310a/310b to the exposed photoresist layer 240. In some embodiments, the pattern is used to etch the middle layer 230a. In turn, the etched middle layer 230a may be used as a masking element to pattern the underlayer 220. In some other embodiments, one or more of the layers on the substrate 210 may also be patterned using subsequent etching processes such as dry etching or plasma etching based on the pattern provided by the pattern of the PR layer 240. The pattern may be insoluble to a positive tone developer.

As mentioned above, since the acid diffusion issue in the top region of the PR layer 240 is improved, and the acid diffusion in the bottom region of the PR layer 240 is facilitated, the tapered top and/or footing profile of the pattern of the PR layer 240 can be improved.

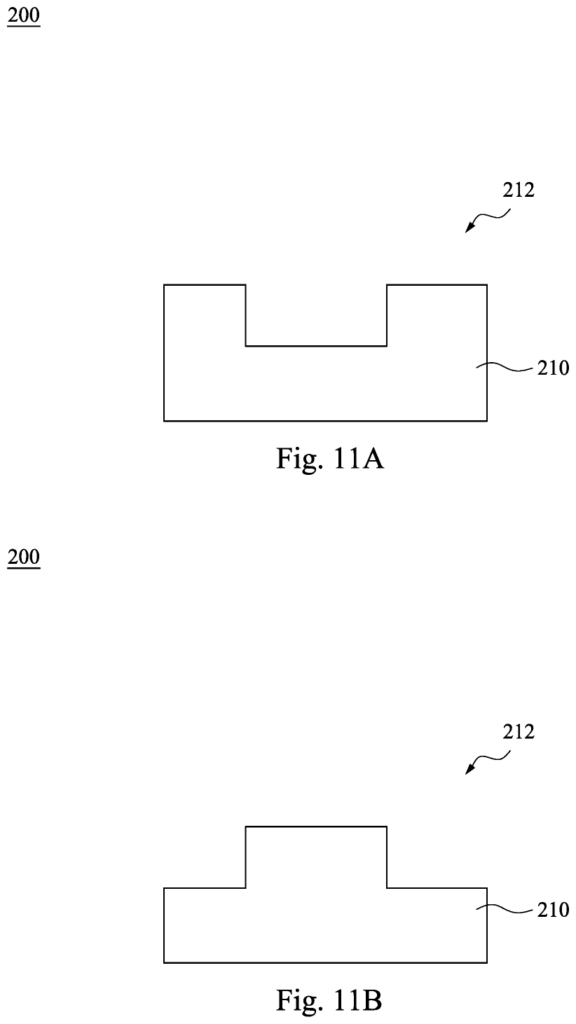

The method 100 then proceeds to operation S122 where a masking element is used to form a semiconductor device feature. In some embodiments, the masking element includes one or more of the photoresist layer, the middle layer, and the underlayer. In some further embodiments, the PR layer 240 is stripped after transferring the pattern to the middle layer 230a (by suitable etching process discussed above). The patterned middle layer 230a may then be used as the masking element to pattern additional layer(s). Referring to the example of FIGS. 11A and 11B, features 212 are formed of a target layer of the substrate 210. The features 212 are defined by the pattern in the PR layer 240 (see FIGS. 10A and 10B). The features 212 may be gate structures, fin structures such as provided in a fin-type field effect transistor, interconnect structures, isolation features, conductive features such as lines, and/or other suitable semiconductor device features.

The method 100 may continue with further operations not specifically described herein. For example, the semiconductor device 200 may next be subjected to a rinsing process, such as a de-ionized (DI) water rinse. The rinsing process may remove residue particles.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the porous (roughed) top surface of the middle layer modifies the PDQ concentration in the PR layer during the soft-baking process, such that the profile of the patterned PR layer can be improved. Another advantage is that the porous/roughed top surface of the middle layer can be formed by adding sacrificial additives in the middle layer.

According to some embodiments, a method includes depositing a middle layer over a substrate. The middle layer includes sacrificial additives. A heating process is performed to cross-link the middle layer. The sacrificial additives are floated onto a top surface of the middle layer. The sacrificial additives are removed from the middle layer after the heating process is performed. A photoresist layer is deposited over the middle layer. The photoresist layer is exposed to a radiation beam. The photoresist layer is developed after the photoresist layer is exposed.

According to some embodiments, a method includes forming a middle layer over a substrate. The middle layer has a porous top surface with a plurality of holes. A photoresist layer is deposited over the middle layer. The photoresist layer includes photo decomposable quenchers (PDQs), and portions of the photoresist layer are disposed in the holes of the porous top surface of the middle layer. A heating process is performed to the photoresist layer and the middle layer. The heating process modifies a distribution of the PDQs in the photoresist layer. The photoresist layer is exposed to a radiation beam. The photoresist layer is developed after the photoresist layer is exposed.

According to some embodiments, a method includes depositing a middle layer with sacrificial additives over a substrate. The middle layer includes polymers, and the polymers and the sacrificial additives are non-cross-linked. A first heating process is performed to the middle layer to cross-link the non-cross-linked polymers while the sacrificial additives remain non-cross-linked. A solvent is provided to the sacrificial additives to remove the sacrificial additives after the first heating process is performed. A photoresist layer is deposited over the middle layer after the sacrificial additives are removed. The photoresist layer is exposed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
depositing a middle layer over a substrate, wherein the middle layer comprises sacrificial additives;
performing a heating process to cross-link the middle layer, wherein the sacrificial additives are floated onto a top surface of the middle layer;
after performing the heating process, removing the sacrificial additives from the middle layer;
depositing a photoresist layer over the middle layer;
exposing the photoresist layer to a radiation beam; and
developing the photoresist layer after exposing the photoresist layer.

2. The method of claim 1, wherein the sacrificial additives are about 500 ppm to about 10% by weight in the middle layer.

3. The method of claim 1, wherein the sacrificial additives comprise polyacrylate, polymethacrylate, polyflouroalcohol, polyester, polyimide, or polyether.

4. The method of claim 1, wherein the sacrificial additives comprise a perfluoroalkyl sidechain.

5. The method of claim 1, wherein the sacrificial additives comprise CₓF_{y}, wherein x is 1 to 10.

6. The method of claim 1, wherein the heating process is performed at a temperature of about 80° C. to about 250° C.

7. The method of claim 1, wherein the sacrificial additives are removed by using a solvent.

8. A method comprising:
forming a middle layer over a substrate, wherein the middle layer has a porous top surface with a plurality of holes;
depositing a photoresist layer over the middle layer, wherein the photoresist layer comprises photo decomposable quenchers (PDQs), and portions of the photoresist layer are disposed in the holes of the porous top surface of the middle layer;
performing a heating process to the photoresist layer and the middle layer, wherein the heating process modifies a distribution of the PDQs in the photoresist layer;
exposing the photoresist layer to a radiation beam; and
developing the photoresist layer after exposing the photoresist layer.

9. The method of claim 8, wherein a depth of the holes is in a range from about 10 nm to about 100 nm.

10. The method of claim 8, wherein the holes occupy about 1% to about 50% by area in the porous top surface of the middle layer.

11. The method of claim 8, wherein the middle layer is substantially photo-acid-generator-free.

12. The method of claim 8, wherein the middle layer is a silicon-containing layer.

13. The method of claim 8, wherein the photoresist layer is a carbon-containing layer.

14. The method of claim 8, wherein the heating process is performed at a temperature of about 70° C. to 250° C.

15. A method comprising:
depositing a middle layer with sacrificial additives over a substrate, wherein the middle layer comprises polymers, and the polymers and the sacrificial additives are non-cross-linked;
performing a first heating process to the middle layer to cross-link the polymers while the sacrificial additives remain non-cross-linked;
after performing the first heating process, providing a solvent to the sacrificial additives to remove the sacrificial additives;
after removing the sacrificial additives, depositing a photoresist layer over the middle layer; and
exposing the photoresist layer.

16. The method of claim 15, wherein a concentration of photo-acid generators in the photoresist layer is greater than a concentration of photo-acid generators in the middle layer.

17. The method of claim 15, wherein the sacrificial additives comprise a perfluoroalkyl sidechain.

18. The method of claim 15, wherein the solvent comprises Propylene glycol monomethylether, Propylene glycol monomethylether acetate, n-butyl acetate, or combinations thereof.

19. The method of claim 15, wherein the photoresist layer comprises photo decomposable quencher (PDQs), and the method further comprises:
performing a second heating process to the photoresist layer, wherein after performing the second heating process, a concentration of the PDQs in the photoresist layer decreases downwardly.

20. The method of claim 15, further comprising depositing an underlayer over the substrate prior to depositing the middle layer, wherein the middle layer is deposited over the underlayer.
